(19) United States
(12) Patent Application Publication
(10) Pub. No.: US 2024/0183766 A1
(43) Pub. Date: Jun. 6, 2024

(54) APPARATUS AND METHOD FOR MEASURING VISCOSITY

(71) Applicant: QUANTUM BIOMETRONICS PRIVATE COMPANY, Heraklion Crete (GR)

(72) Inventors: Iannis KOMINIS, Heraklion (GR); Christoforos Thalassinakis, Heraklion Crete (GR); Panagiotis Karavelas, Heraklion Crete (GR)

(21) Appl. No.: 18/062,391

(22) Filed: Dec. 6, 2022

(51) Int. Cl. G01N 11/10; G01R 33/06

(52) U.S. Cl. CPC G01N 11/10; G01R 33/066; G01N 2011/0086

(57) ABSTRACT

An apparatus for measuring the viscosity of fluid, including a container having a first end and a second end. The container is configured for holding fluid between the first and second ends. The apparatus further includes a moving body made of magnetic material configured to travel along a trajectory inside the container between the first and second ends, and at least one magnetic sensor configured for measuring changes in a magnetic field produced by the moving body during the travel. The apparatus further includes a memory device having prestored information related to dependencies between magnetic field variations along the trajectory and a viscosity of the fluid. The apparatus further includes a processor configured to determine viscosity of the fluid corresponding to the measured changes in accordance with the prestored information.

### FIELD OF INVENTION

The presently disclosed subject matter relates to a viscometer in general and in particular to a viscometer of the type of the falling-sphere, wherein the sphere falls in the liquid, the viscosity of which is being measured.

### BACKGROUND ART

References considered to be relevant as background to the presently disclosed subject matter are listed below:
[1] Apparatus and method for viscosity measurement using a portable field viscometer, US 2022/0252495 A1

### BACKGROUND

There are several types of viscometers, like (i) mechanical viscometers, among which there are falling sphere viscometers, capillary viscometers, and rotational/vibrational viscometers, (ii) microfluidic or micro/nano-mechanical viscometers and (iii) electro-mechanical viscometers, where some electric or magnetic interaction is coupled to the fluid's viscosity.

Existing falling sphere viscometers measure the terminal velocity of the sphere in the fluid under test. The terminal velocity is achieved when the three forces acting on the sphere are balanced, that is, the downward gravity force is balanced by the upward buoyant force and the upward Stokes resistive force. It is the latter that depends on the fluid's viscosity. The terminal velocity is achieved some time during the fall, and the fluid column must be high enough that the falling sphere has enough pathlength to achieve the terminal velocity before hitting the bottom of the container. Achieving the terminal velocity is important for these viscometers, because the terminal velocity is a well-defined velocity characteristic of the sphere's motion in the fluid, and moreover the terminal velocity is directly connected to the fluid's viscosity. Indeed, considering that the three forces acting on the falling sphere are:
(i) the downward gravitational force

F_{g}=mₛg (1)

where g is the gravitational constant, mₛ=(4π/3) r³ρs is the mass of the sphere given in terms of its radius r and its mass density ρ_{S},
(ii) the upward buoyant force

F_{b}=m_{f}g (2)

where m_{f}=(4π/3)r³ρ_{f} is the mass of the fluid being displaced by the sphere, given in terms of the ball's radius r and the fluid's mass density ρ_{f}, and
(iii) the Stokes force

Fₛₜₒₖₑₛ=6ηπrν (3)

where η is the viscosity of the fluid, and v is the velocity of the falling sphere. The sphere reaches its terminal velocity vₜ when force equilibrium has been established, that is, when

F_{g}=F_{b}+Fₛₜₒₖₑₛ (4)

From that point on, the sphere's velocity remains constant at the value vₜ. In other words, the ball starts to fall from rest (v=0), then it accelerates (v is increasing) but with diminishing acceleration, until v=vₜ. Solving the force equilibrium equation (4) for the viscosity η, one obtains

$$η = \frac{2}{9} \frac{g {r}^{2} ( {ρ}_{s} - {ρ}_{f} )}{{v}_{t}} \qquad ( 5 )$$

To find the terminal velocity vₜ one has to measure the time it takes the sphere to travel between two points inside the container. Hence it is required to establish two markers along the sphere's trajectory, allowing thereby to determine the exact time the sphere passes through each of the markers, and the travel time between these two markers. The travel time and the distance between the two markers provides the terminal velocity vₜ of the sphere traveling between these markers. The markers can be for example laser or magnetic sensors.

### SUMMARY OF INVENTION

There is provided according to one aspect of the presently disclosed subject matter an apparatus for measuring the viscosity of fluid, including a container having a first end and a second end. The container is configured for holding fluid between the first and second ends. The apparatus further includes a moving body made of magnetic material configured to travel along a trajectory inside the container between the first and second ends, and at least one magnetic sensor configured for measuring changes in a magnetic field produced by the moving body during the travel. The apparatus further includes a memory device having prestored information related to dependencies between magnetic field variations along the trajectory and a viscosity of the fluid. The apparatus further includes a processor configured to determine viscosity of the fluid corresponding to the measured changes in accordance with the prestored information.

The prestored information can include a formula configured for calculating magnetic field variations for a certain viscosity and wherein the processor is configured to calculate magnetic field variations for various viscosities and to compare data obtained by the magnetic sensor with results of the formula.

The processor can be configured to compare the data with results of the formula by a nonlinear curve fitting algorithm.

The prestored information can include a plurality of datasets each of which including a series of pairs of magnetic field value and an instant of time for a certain viscosity.

The moving body can be configured to gravitate from the first end towards the second end.

The magnetic material can be Neodymium.

The moving body can include liquid having magnetic properties. The moving body can be a sphere. The moving body can be a cylinder.

The apparatus can further include a current-carrying solenoid configured to hold the moving body at the first end.

The solenoid can be disposed such that an axis thereof is parallel to the trajectory such that magnetization of the moving body is oriented along the axis.

The at least one magnetic sensor can be positioned midway along the trajectory, and is disposed such that sensitive axis of the magnetic sensor is at an angle with respect to the trajectory.

The at least one magnetic sensor can include two magnetic sensors positioned at two different fixed positions along the trajectory, generating thereby a first signal and a second signal, and wherein the processor is configured to subtract the first signal from the second signal eliminating thereby ambient magnetic field.

The container and the magnetic sensor can be disposed inside a magnetic shield configured to eliminate ambient magnetic field.

There is provided according to yet one aspect of the presently disclosed subject matter a method for measuring the viscosity of fluid. The method includes disposing the fluid in a container having a first end and a second end, urging a moving body made of magnetic material to travel along a trajectory inside the container between the first and second ends. The method further includes measuring with at least one magnetic sensor changes in a magnetic field produced by the moving body during the travel, assessing prestored information related to dependencies between magnetic field variations along the trajectory and a viscosity of the fluid, and determining viscosity of the fluid corresponding to the measured changes in accordance with the prestored information.

The prestored information can include a formula configured for calculating magnetic field variations for a certain viscosity and wherein the step of assessing includes calculating magnetic field variations for various viscosities and comparing data obtained by the magnetic sensor with results of the formula.

The step of comparing the data with results of the formula can include fitting the obtained data in a nonlinear curve fitting algorithm.

The prestored information can include a plurality of datasets each of which including a series of pairs of magnetic field value and an instant of time for a certain viscosity.

### BRIEF DESCRIPTION OF THE DRAWINGS

FIG. 1 is a side view of an apparatus for measuring viscosity in accordance with an example of the presently disclosed subject matter;

FIG. 2 is a diagram representation of the magnetic field in the apparatus of FIG. 1;

FIG. 3A is a graph representing a time-dependent magnetic field for an apparatus in accordance with an example of the presently disclosed subject matter having a single magnetic sensor;

FIG. 3B is a graph representing a time-dependent magnetic field for apparatus in accordance with another example of the presently disclosed subject matter having two magnetic sensors;

FIG. 4 is a side perspective view of a container having a current-carrying solenoid in accordance with an example of the presently disclosed subject matter; and

FIG. 5 is a bottom perspective view of the container of FIG. 3.

### DETAILED DESCRIPTION OF EMBODIMENT

The presently disclosed subject matter includes a method for determining viscosity of fluids by detecting a time-dependent magnetic field during the travel of the moving body, which can be a sphere, inside the fluid container. This can be carried out by providing a sphere which is made out of or includes magnetic material. Consequently, the magnetic field produced by the sphere changes depending on the location of the sphere inside the container. The time-dependent magnetic field provides a dataset including time stamps and measured magnetic field for each time stamp. Since the rate of changes in the magnetic field during the travel of the sphere is directly related to the viscosity of the fluid, the viscosity can be determined in accordance with the changes in the magnetic field.

This is contrary to prior art devices in which viscosity is determined by calculating the speed in which the sphere travels, in accordance with the time of travel and the length of the trajectory.

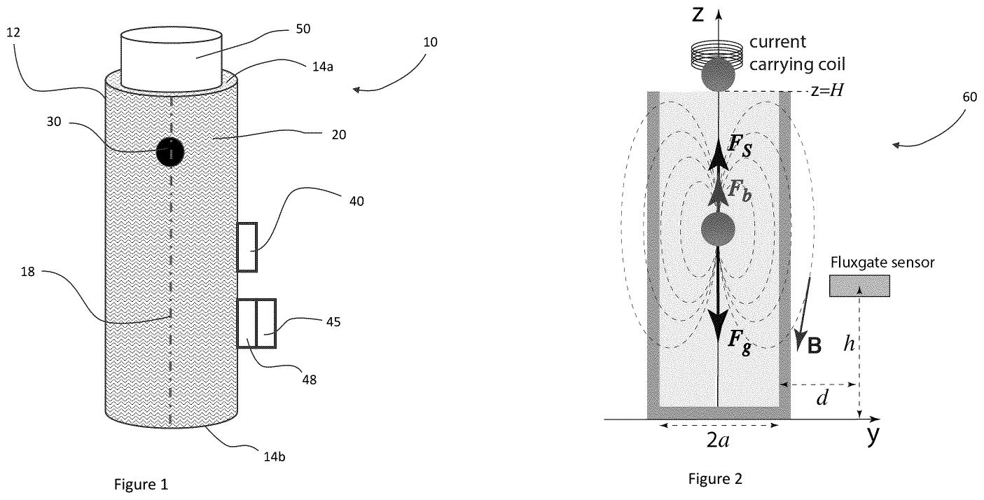

As shown in FIG. 1, the method can be implemented by an apparatus 10, including a container 12 having a first and second ends, here illustrated as a top end 14a and a bottom end 14b. The container 12 is configured for holding fluid 20 between the top end 14a and the bottom end 14b.

The apparatus 10 further includes a moving magnet, here illustrated as a sphere 30 made of magnetic material configured to travel along a trajectory 18 inside the container 12 between the top and bottom ends 14a and 14b. The trajectory 18 can extend along the entire length of the container, or a portion thereof.

As a result, when the sphere 30 travels inside the container 12, the magnetic field around the container changes depending on the location of the sphere 30. According to the shown example, the sphere 30 travels from the top end 14a of the container along a vertical trajectory 18 towards the bottom end 14b as a falling object driven by gravity forces. However, according to other examples, the container can be a horizontal container and the sphere 30 can be configured to travel along a horizontal trajectory between two ends of the container. According to this example, the sphere 30 can be urged to travel by forces acting on the sphere 30, other than gravity.

The magnetic material can be, like Neodymium, or other magnetic material, which could be solid or even liquid, like a ferrofluid.

The apparatus 10 further includes a magnetic sensor 40 configured for measuring changes in the magnetic field produced by the sphere 30. The magnetic sensor 40 is thus disposed at a fixed location with respect to the container 12, and is configured to provide data related to the magnetic field during the travel time. In other words, the magnetic sensor 40 provides data related to the changes in the magnetic field during a time period, during which the sphere 30 travels inside the fluid. The magnetic sensor 40 can be a fluxgate magnetometer, or any other magnetometer, which can measure the magnetic field produced by the magnetized sphere.

The apparatus further includes a memory device 45 having prestored information related to dependencies between magnetic field variations along the trajectory and a viscosity of the fluid. The prestored information can be a formula configured for calculating magnetic field variations for a certain viscosity, such that magnetic field variations for various viscosities can be calculated. An example of such formula is described hereinafter.

Finally, the apparatus 10 includes a processor 48 configured to determine viscosity of the fluid corresponding to the measured changes in accordance with the prestored information. In other words, the processor can be configured to calculate magnetic field variations for a certain viscosity in accordance with the formula stored in the memory device 45. The processor is further configured to compare the data obtained by the magnetic sensor 40 with the magnetic field variations calculated with the formula for a certain viscosity. This can be carried out for example by feeding the measured data into a nonlinear curve fitting algorithm in order to extract the fluid's viscosity. Such nonlinear curve fitting algorithms are for example the nonlinear least-squares fitting, the Levenberg-Marquardt algorithm, the Downhill Simplex algorithm or other mathematical fitting algorithms.

According to another example prestored information in the memory device 45 can be a plurality of datasets each of which including a series of pairs of magnetic field value and an instant of time for a certain viscosity. This way, each dataset includes the magnetic field variations for a certain viscosity. This dataset can be collected by conducting a series of test during which the same sphere 30 travels along the same trajectory inside the same container 12. The only parameter which changes between the various tests is the viscosity of the fluid inside the container 12. Thus, the prestored data provides the expected magnetic field changes during the travel of the sphere 30 for various viscosities. According to another example, the prestored data can include theoretical data obtained by conducting a set of calculations as explained hereinbelow.

According to the latter example, in which the memory device 45 includes a plurality of datasets, the processor 48 can be configured to locate the dataset which most closely matches the data obtained by the magnetic sensor 40.

It would be appreciated that the magnetic sensor 40 can be configured to output voltage for the entire travel duration of the sphere. The voltage output can be digitized with some analog-to-digital converter, and the result is a plurality of pairs of voltage value and an instant of time when the voltage value was measured.

The following explanation refers an example of a formula for calculating magnetic field variations for a certain viscosity, with reference to the diagram 60 of FIG. 2.

The magnetized sphere produces in space a magnetic field, which depends on (i) the orientation in space of the sphere's magnetization, described by the three-dimensional vector M, and (ii) the position vector of the point of interest with respect to the sphere, described by the vector r. The so-called dipole magnetic field produced by a magnetized sphere having magnetization M is given by

$$B ( r ) = \frac{{μ}_{0}}{4 π} ( 3 \frac{( M \cdot r ) r}{{r}^{5}} - \frac{M}{{r}^{3}} ) \qquad ( 6 )$$

where μ₀=4π*10⁻⁷ H/m is the vacuum's magnetic permeability, r=|r| is the magnitude of the position vector r, and M·r is the inner product between the magnetization vector and the position vector.

Contrary to traditional falling-sphere viscometer, according to the present invention the fall of the sphere 30 in the fluid can be continuously monitored by the magnetic sensor 40, since the magnetic field produced by the falling sphere at the fixed position of the magnetic sensor is continuously changing. This is so because the position vector, r, of the magnetic sensor with respect to the sphere is changing with time during the sphere's fall. This changing position vector enters equation (6) determining the magnetic field at the fixed position of the sensor.

Thus, according to the present invention changes in the magnetic field are measured for the whole trajectory of the sphere, since this trajectory is conveyed by the magnetic field produced by the falling magnetized sphere. Thus, the obtained data is a time-dependent magnetic field during the entire fall of the magnetic sphere from the top of the fluid's container to the bottom.

In more detail, the method of the present invention does not rely on the force equilibrium equation (4), indicated above, but on the whole trajectory of the falling sphere, which can be obtained by solving the time-dependent equation of motion. This reads:

mₛ\ddot{z}(t)=−F_{g}+F_{b}+Fₛₜₒₖₑₛ (7)

where z(t) is the sphere's height as a function of time, and \ddot{z}(t) is the second time derivative of z(t) (acceleration). The time-dependent velocity of the sphere is given by the first time derivative of z(t), hence it is v(t)=ż(t). It is this time-dependent velocity that now enters the Stokes force F_{Stokes} appearing in equation (7), with the expression for the Stokes force being given by equation (3).

By solving the time-dependent equation of motion (7), the height z(t) can be explicitly found. It is

$$z ( t ) = H + g λ {τ}^{2} ( 1 - \frac{t}{τ} - {e}^{- t / τ} ) \qquad ( 8 )$$

where H is the initial height of the sphere on top of the fluid column, λ=1−ρ_{f}/ρ_{S}, and

$$τ = \frac{2 {ρ}_{s} {r}^{2}}{9 η} \qquad ( 9 )$$

The time constant τ entering the trajectory z(t) carries the information on the fluid's viscosity η, and characterizes the whole trajectory.

Now, the magnetic sensor measures the component of magnetic field at its position along some direction defined by the sensor and described by the unit vector \hat{n}. The time-dependent magnetic field measured by the magnetic sensor is then given by

B(t)=\hat{n}·B(r) (10)

where r is the position vector from the center of the sphere to the magnetic sensor, and B(r) is given by equation (6). The magnetic sensor will transduce the time-dependent magnetic field B(t) into a time-dependent voltage V(r), which is readily registered. The position vector r is given by

r=(d+a)ŷ+(h−z(t))\hat{z} (11)

where d is the distance between the sensor and the container of the fluid, 2a is the width of the container of the fluid, h is the position of the magnetic sensor along the z-axis which is the axis of the sphere's motion, while ŷ and \hat{z} are unit vectors along the y-axis and the z-axis, respectively. The distances d, a and h are shown in FIG. 2. The measurement relies on the fact that (i) the sphere's height z(t) depends on the parameter τ, which depends on the fluid's viscosity η, (ii) the sphere's height z(t) enters the position vector r, (iii) the position vector r determines the magnetic field measured by the magnetic sensor through equation (6).

According to the example shown in FIG. 2, the magnetic sensor is sensitive along the y-axis, which means that \hat{n}=ŷ, but any other sensor direction is admissible.

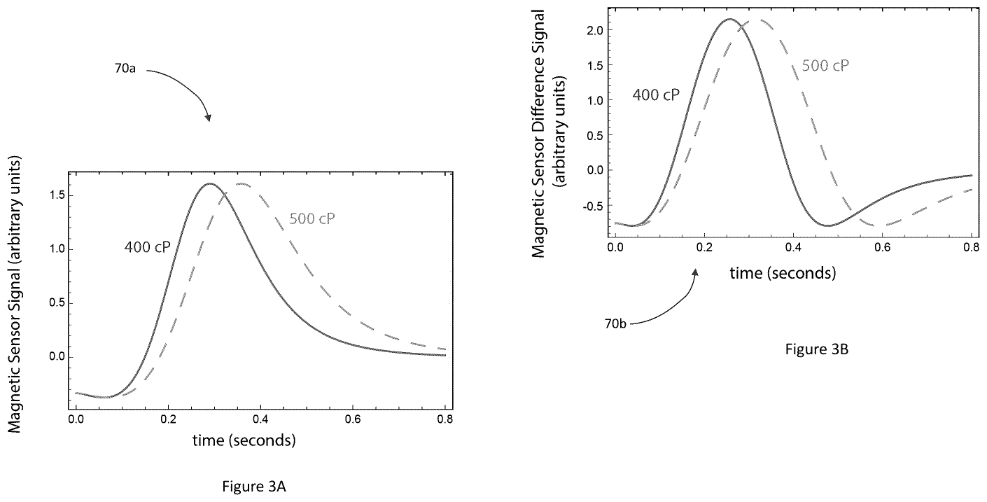

With reference to FIG. 3A, the result of the above equations can be presented in a graph 70a, showing the changes in the magnetic field as a function of time. The changes in the magnetic field are represented here in arbitrary units, however according to other examples the changes can be presented in terms of voltage output by the magnetic sensor 40. As shown in the graph 70a, changes in the magnetic field are calculated for two different values of the viscosity of the fluid, η=400 cP (presented by the solid line), and η=500 cP (presented by the dashed line). It is noted that for this graph, the calculations are made assuming the following dimensions of the container: H=4.4 cm, h=2.2 cm, a=0.5 cm, d=1.5 cm, as shown in FIG. 2. Similarly, the ratio of the densities is taken as ρ_{f}/ρₛ=0.1, and the mass and radius of the sphere is mₛ=0.08 g and r=1 mm, respectively.

Thus, it can be seen that the manner in which the magnetic field changes during the course of the movement of the sphere differs depending on the viscosity of the fluid.

Furthermore, the above method can be implemented with two sensors, in order to remove the background magnetic field at the position of the single sensor discussed before. By using two sensors and subtracting their measured records, B₁(t)−B₂(t), the background field B₀ generated by earth's field or any other local magnetic fields can be removed, since B₁(t)=Bₛ₁(t)+B₀, and B₂(t)=Bₛ₂(t)+B₀, where Bₛ₁(t) is the magnetic field produced by the sphere at the position of sensor 1, and Bₛ₂(t) is the magnetic field produced by the sphere at the position of sensor 2. This arrangement is a magnetic gradiometer arrangement, and it removes the background field B₀, which is supposed to be the same at the position of both sensors, since it is generated by sources far from the sensors.

For example, as shown in FIG. 3B, according to the latter example, the result of the above equations can be presented in a graph 70b, showing the changes in the magnetic field as a function of time. In the graph 70b, however, the changes in the magnetic field are detected by two magnetic sensors disposed along the trajectory 18. According to the illustrated graph the magnetic sensors are calculated with a first heights h₁=3 cm and h₂=1 cm, relative to the bottom end 14b of the container.

Another way to remove the background field is to use one magnetic sensor, and have the whole apparatus including the container, the sensor, and the magnetic sphere be disposed inside a magnetic shield configured to eliminate ambient magnetic field.

In order to obtain the magnetic sensor signal B(t) of equation (10), one has to know the direction of the sphere's magnetization M. According to an example, the apparatus 10 includes a current-carrying solenoid 50 configured to hold the sphere 30 on top of the fluid container 12. By switching off the current, the sphere 30 commences its fall. Another use of the solenoid is that it aligns the magnetization of the sphere along the solenoid axis, which is the axis along the sphere's trajectory 18. Thus, the solenoid 50 has a dual role.

According to another example, in order to avoid any uncertainty in the direction of the sphere's magnetization, instead of the sphere, the magnet body can be a cylindrical magnet with its magnetization along the cylinder's axis. The advantage of the cylindrical magnet is that the direction of magnetization is fixed along its axis.

The axis of the solenoid can be parallel to the trajectory of the falling sphere, so that the magnetization of the magnetic sphere is oriented along the axis. Moreover, the magnetic sensor can be positioned midway along the trajectory, and with its sensitive axis orthogonal to the trajectory or at an angle with respect to the trajectory. This way, the magnetic field produced by the sphere, the magnetization of which is oriented along the axis of the solenoid, has a positive contribution to the magnetic field measured by the sensor in the first half of the trajectory, and a negative contribution to the magnetic field measured by the sensor in the second half of the trajectory.

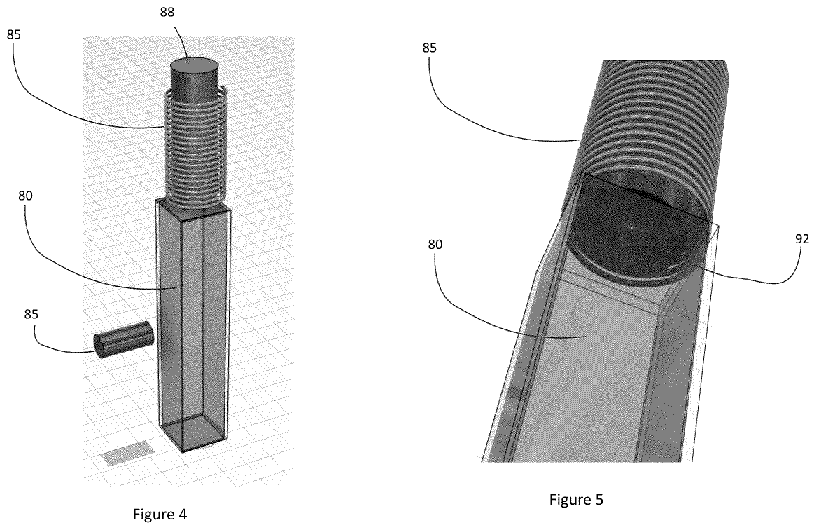

An example of a container 80 having a solenoid 85 is shown in FIGS. 4 and 5. The solenoid 85 can include a nonmagnetic metal cylinder 88, around which there is wrapped a solenoid 85. The magnetic sensor 90 according to this example is disposed transverse to the long axis of the container, which is the sphere's axis of motion. The long axis of the container defines the z-axis, and the axis of the sensor the y-axis.

It is noted that the solenoid 85 and magnetic sensor 90 can be controlled by the processor, such that once the current in the solenoid 85 is turned off allowing the sphere 92 to gravitate, the magnetic sensor 90 initiates the detection of the magnetic field.

Finally, in order to extract the fluid's viscosity n from the measured time-dependent magnetic sensor signal B(t), or equivalently, its transduced voltage V(t), one needs to fit the measured data to the theoretical form resulting from equation (10). Once the density, ρ_{S}, of the fluid and the geometry of the setup (distances a, d, h, H) are known, the only free parameter in the theoretical form resulting from equation (10) is the viscosity n. In particular, the magnetic sensor output voltage V(t) is digitized with some analog-to-digital converter, and the result is a number N of pairs (tⱼ,V(tⱼ)), where j=1, 2, . . . , N, and where tⱼ are the instants in time when the voltage V(t) is sampled, with V(tⱼ) being the respective sampled values. The N data points (tⱼ,V(tⱼ)), together with the theoretical form resulting from equation (10) are then fed into a nonlinear curve fitting algorithm in order to extract the fluid's viscosity η, that is, find the value of n for which the theoretical calculation of equation (10) best matches the N data points. As indicated above, such nonlinear curve fitting algorithms are for example the nonlinear least-squares fitting, the Levenberg-Marquardt algorithm, the Downhill Simplex algorithm or other mathematical fitting algorithms.

According to an example, the apparatus can further include a small magnet at the bottom of the fluid container in order to attract the sphere 30 and to urge the sphere 30 to travel along the trajectory. This small magnet will have the effect of better aligning the sphere's magnetization with the axis of motion, suppressing any rotation of the falling body during its fall. The apparatus may also include guiding magnets disposed along the length of the container so as to guide the trajectory of the moving body.

According to a further example, the magnetic sphere can be replaced with a liquid body such as a ferrofluid. In this case one can monitor the ferrofluid's diffusive motion in the fluid under test with the magnetic sensor.

It is noted that one of the advantages of the device of the present invention is that since it measures the continuous trajectory of the falling body in the fluid under test, and since it does not require the falling body to have reached terminal velocity, the fluid column height can be small. In addition, since the magnetic falling body produces a large signal in the magnetic sensor, the size of the falling body can also be very small. As a result of the above a relatively small volume of fluid is required, for example 5 ml or less.

Furthermore, according to the present invention, the whole measurement lasts for as long as it takes the falling body to reach the bottom of the fluid column, which is on the order of a second (for example, for oils). Thus a further advantage of the present invention is a precise measurement (the precision determined by the intrinsic noise of the magnetic sensor), a fast measurement, and a measurement with a small fluid sample volume.

According to an example, the sphere can be made of iron, however in this case the magnetic signal at the sensor would be rather small. Thus, a sensitive magnetic sensor can be included so as to measure the magnetic field changes resulting from the displacement of the iron sphere.

Those skilled in the art to which the presently disclosed subject matter pertains will readily appreciate that numerous changes, variations, and modifications can be made without departing from the scope of the invention, mutatis mutandis.

1. An apparatus for measuring the viscosity of fluid, the apparatus comprising:
a container having a first end and a second end, said container is configured for holding fluid between said first and second ends;
a moving body made of magnetic material configured to travel along a trajectory inside the container between said first and second ends;
at least one magnetic sensor configured for measuring changes in a magnetic field produced by said moving body during said travel;
a memory device having prestored information related to dependencies between magnetic field variations along said trajectory and a viscosity of the fluid;
a processor configured to determine viscosity of the fluid corresponding to said measured changes in accordance with said prestored information.

2. The apparatus of claim 1 wherein the prestored information includes a formula configured for calculating magnetic field variations for a certain viscosity and wherein said processor is configured to calculate magnetic field variations for various viscosities and to compare data obtained by the magnetic sensor with results of said formula.

3. The apparatus of claim 2 wherein said processor is configured to compare said data with results of said formula by a nonlinear curve fitting algorithm.

4. The apparatus of claim 1 wherein the prestored information includes a plurality of datasets each of which including a series of pairs of magnetic field value and an instant of time for a certain viscosity.

5. The apparatus of claim 1 wherein the moving body is configured to gravitate from said first end towards said second end.

6. The apparatus of claim 1 wherein the magnetic material is Neodymium.

7. The apparatus of claim 1 wherein the moving body includes liquid having magnetic properties.

8. The apparatus of claim 1 wherein the moving body is a sphere.

9. The apparatus of claim 1 wherein the moving body is a cylinder.

10. The apparatus of claim 1 further comprising a current-carrying solenoid configured to hold said moving body at said first end.

11. The apparatus of claim 10 wherein the solenoid is disposed such that an axis thereof is parallel to the trajectory such that magnetization of the moving body is oriented along said axis.

12. The apparatus of claim 1 wherein said at least one magnetic sensor is positioned midway along the trajectory, and is disposed such that sensitive axis of said magnetic sensor is at an angle with respect to the trajectory.

13. The apparatus of claim 1 wherein said at least one magnetic sensor includes two magnetic sensors positioned at two different fixed positions along the trajectory, generating thereby a first signal and a second signal, and wherein said processor is configured to subtract said first signal from said second signal eliminating thereby ambient magnetic field.

14. The apparatus of claim 1 wherein the container and said magnetic sensor are disposed inside a magnetic shield configured to eliminate ambient magnetic field.

15. The apparatus of claim 1 further comprising guiding magnets disposed along length of the container so as to guide the trajectory of the moving body.

16. A method for measuring the viscosity of fluid, the method comprising:
disposing the fluid in a container having a first end and a second end;
urging a moving body made of magnetic material to travel along a trajectory inside the container between said first and second ends;
measuring with at least one magnetic sensor changes in a magnetic field produced by said moving body during said travel;
assessing prestored information related to dependencies between magnetic field variations along said trajectory and a viscosity of the fluid;
determining viscosity of the fluid corresponding to said measured changes in accordance with said prestored information.

17. The method according to claim 16 wherein the prestored information includes a formula configured for calculating magnetic field variations for a certain viscosity and wherein said step of assessing includes calculating magnetic field variations for various viscosities and comparing data obtained by the magnetic sensor with results of said formula.

18. The method according to claim 17 wherein said step of comparing said data with results of said formula includes fitting the obtained data in a nonlinear curve fitting algorithm.

19. The method according to claim 16 wherein the prestored information includes a plurality of datasets each of which including a series of pairs of magnetic field value and an instant of time for a certain viscosity.
